(19) United States
(12) Patent Application Publication
(10) Pub. No.: US 2008/0149488 A1
(43) Pub. Date: Jun. 26, 2008

(54) SOLVENT-SOLUBLE STAMP FOR NANO-IMPRINT LITHOGRAPHY AND METHOD OF MANUFACTURING THE SAME

(75) Inventors: Byung kyu LEE, Seoul (KR); Myung bok LEE, Suwon-si (KR); Jin Seung SOHN, Seoul (KR); Du hyun LEE, Suwon-si (KR); Eun Hyung CHO, Seoul (KR); Hae sung KIM, Hwaseong-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/842,443

(22) Filed: Aug. 21, 2007

(30) Foreign Application Priority Data
Dec. 21, 2006 (KR) 10-2006-0132164

(51) Int. Cl. B41C 3/08; C23C 16/00

(52) U.S. Cl. 205/127; 427/255.28

(57) ABSTRACT

A method of manufacturing a solvent-soluble stamp for nano-imprint lithography is provided. According to the method, a stamp is formed on a master substrate made of an ultraviolet-transparent material, using a material which is soluble in a solvent, and then a metal stamp or another stamp for a nano-imprint lithography is manufactured using the solvent-soluble stamp. Next, the stamp for nano-imprint lithography can be achieved by melting the soluble stamp. Therefore, it is possible to reuse the master several times. Further, it is possible to solve a problem in which a mold cannot be separated from the stamp. Furthermore, a uniform and clean stamp with a nano size can be obtained.

This application claims priority from Korean Patent Application No. 2006-0132164 filed on Dec. 21, 2006, in the Korean Intellectual Property Office, the disclosure of which is incorporated herein by reference in its entirety.

### BACKGROUND OF THE INVENTION

1. Field of the Invention

Methods consistent with the present invention relate to a method of manufacturing a solvent-soluble stamp for nano-imprint lithography, and more particularly, to a method of manufacturing a solvent-soluble stamp for nano-imprint lithography, which can duplicate a great number of stamps using a single substrate and manufacture a stamp having a clean and accurate nano-pattern.

2. Description of the Related Art

Nano-imprint lithography is one of the next generation technologies which can overcome the limitation of conventional photo-lithography. Further, nano-imprint lithography has an advantage of remarkably reducing processing costs associated with a high-density of patterning. This nano-imprint technology is a method of lithographing a substrate having a resin or a polymer film deposited thereon by applying energy (i.e., ultraviolet ray or heat) to the substrate after physically contacting a stamp having a nano pattern to the substrate. An aspect in the nano-imprinting is the manufacturing of the stamp. Manufacturing the stamp easily is very important in the nano-imprint lithography process in view of cost and technology. Hereinafter, a conventional method of manufacturing a stamp for nano-imprint lithography will be described with reference to the accompanying drawings.

FIGS. 1A to 1F are sectional views illustrating a conventional method of manufacturing a stamp for nano-imprint lithography.

First, a resist 2 is coated on the upper surface of a substrate 1 made of silicon Si, glass, or quartz, as shown in FIGS. 1A and 1B.

Then, a pattern is formed on the substrate 1 coated with the resist 2 by using a lithography process such as photo-lithography, E-beam lithography, etc.

Next, a pattern is lithographed on the substrate 1 by using a Reaction Ion Etching (RIE) process, in order to make a master substrate 2a, as shown in FIG. 1C.

Continuously, a metal layer 3 is deposited on the master structure by sputtering method, etc., in order to plate the master substrate 2a, thereby allowing electric current to flow through the metal layer 3, as shown in FIG. 1D.

Then, a metal 4 such as nickel Ni or copper Cu is vapor-deposited on the structure shown in FIG. 1D using an electroplating method, as shown in FIG. 1E.

Finally, the plated metal layer 4 is separated from the substrate 1 in order to manufacture the stamp 4 for the nano-imprint lithography.

As described above, in the conventional method of manufacturing the stamp for nano-imprint lithography, a metal layer 3 for electrodes is vapor-deposited on the substrate having a pattern formed thereon, using the sputtering method and then the substrate is used to manufacture the metal stamp 4 by the electroplating method. However, since the cohesion between the substrate 1 with the pattern and the metal electrodes 3 deposited on the substrate 1 by the sputtering method is excellent, the substrate 1 may be damaged or a remainder still may remain on the substrate 1 when the metal stamp 4 is separated from the substrate 1. As a result, it is difficult to manufacture a stamp having a clean and fine pattern.

Further, since the substrate may be physically destroyed, a stamp should only be formed on a single substrate. Thus, since the expensive silicon master substrate can only be used one time, it is difficult to secure a number of stamps which have similar patterns, and there is an inconvenience in which a master substrate corresponding to each stamp is newly manufactured.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above. Accordingly, the present invention provides a method of manufacturing a solvent-soluble stamp for nano-imprint lithography, by which a preform stamp is made of a polymer material, which is soluble in a solvent, after a pattern is formed on a substrate, and then the final stamp is made by using the preform stamp, thereby manufacturing a stamp with a clean and accurate nano-pattern.

According to another aspect of the present invention, there is provided a method of manufacturing a solvent-soluble stamp for nano-imprint lithography, by which a stamp is made of a polymer material, which is soluble in a solvent, after a pattern is formed on a substrate.

According to another aspect of the present invention, there is provided a method of manufacturing a solvent-soluble stamp for nano-imprint lithography, which can duplicate a number of stamps using only one substrate.

In order to achieve the above aspects of the present invention, there is provided a method of manufacturing a solvent-soluble stamp for nano-imprint lithography, the method comprising: (a) forming a pattern on the upper surface of a substrate using a lithography process after a resist is coated on the upper surface of the substrate; (b) etching the substrate using the patterned resist; (c) vapor-depositing a polymer, such as a solvent-soluble resin, on the structure in step (b); (d) physically separating the polymer on which the pattern of the substrate is lithographed from the substrate; (e) vapor-depositing a metal layer for plating on the upper surface of the separated polymer pattern using a sputtering process; (f) vapor-depositing a metal on the upper surface of the structure in step (e) by electroplating method; and (g) solving the structure in step (f) in a solvent to remove the polymer, so as to obtain the stamp for nano-imprint lithography.

According to another exemplary embodiment of the present invention, there is provided a method of manufacturing a solvent-soluble stamp for nano-imprint lithography, the method comprising: (a) forming a pattern on the upper surface of a substrate using a lithography process after a resist is coated on the upper surface of the substrate; (b) etching the substrate using the patterned resist; (c) vapor-depositing a polymer, such as solvent-soluble resin, on the structure in step (b); and (d) physically separating the polymer on which the pattern of the substrate is lithographed from the substrate, so as to obtain the stamp for nano-imprint lithography.

Here, the substrate is made from an ultraviolet-permeable material such as silicon Si, glass, quartz, sapphire, diamond, etc.

Further, the metal deposited on the structure in step (f) includes nickel Ni and copper Cu.

As described above, in the method of manufacturing the stamp for the nano-imprint lithography, a stamp is formed on a master substrate made of an ultraviolet-permeable material such as silicon Si, glass, quartz, sapphire, diamond, etc., using a material which is soluble in a solvent, and then a metal stamp or another stamp for nano-imprint lithography is manufactured using the solvent-soluble stamp. Next, the stamp for the nano-imprint lithography can be achieved by melting the soluble stamp. Therefore, it is possible to reuse the master substrate several times. Further, it is possible to solve a problem in which a mold cannot be separated from the stamp. Furthermore, a uniform and clean stamp with a nano size can be obtained.

### BRIEF DESCRIPTION OF THE DRAWINGS

The above aspects and other features of the present invention will become more apparent by describing in detail exemplary embodiments thereof with reference to the attached drawings in which:

FIGS. 1A to 1F are sectional views illustrating a method of manufacturing a conventional stamp for nano-imprint lithography;

FIGS. 2A to 2J are sectional views illustrating a method of manufacturing a solvent-soluble stamp for nano-imprint lithography according to an exemplary embodiment of the present invention; and

FIGS. 3A to 3G are sectional views illustrating a method of manufacturing a solvent-soluble stamp for nano-imprint lithography according another exemplary embodiment of the present invention.

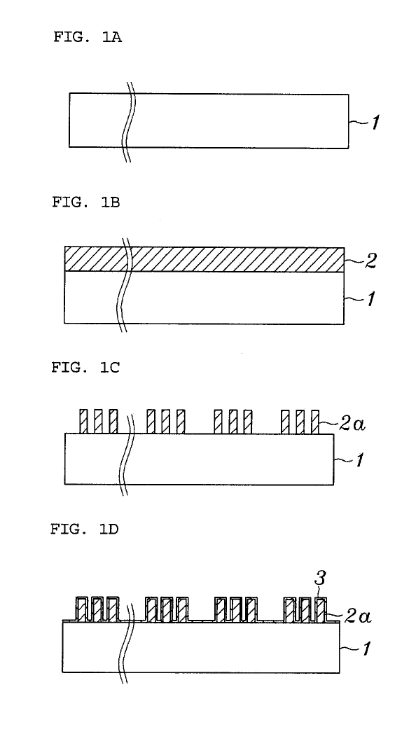

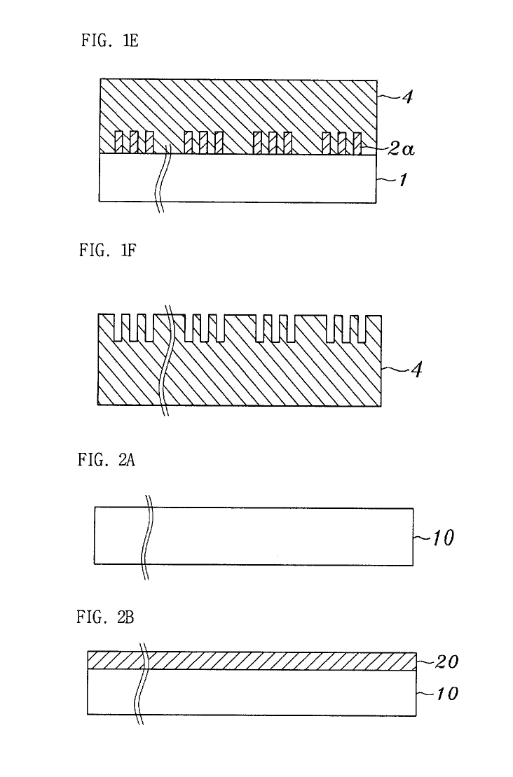

### DETAILED DESCRIPTION OF THE EXEMPLARY EMBODIMENTS OF THE INVENTION

The invention now will be described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art.

The terminology used herein is for the purpose of describing particular embodiments only and is not intended to be limiting of the invention. The terms “a” and “an” do not denote a limitation of quantity, but rather denote the presence of at least one of the referenced item. The term “or” means “and/or”. The terms “comprising”, “having”, “including”, and “containing” are to be construed as open-ended terms (i.e., meaning “including, but not limited to”).

It will be understood that, although the terms first, second, third, etc., may be used herein to describe various elements, steps, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Exemplary embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the exemplary embodiments of the present invention will be described with reference to the accompanying drawings.

### Embodiment 1

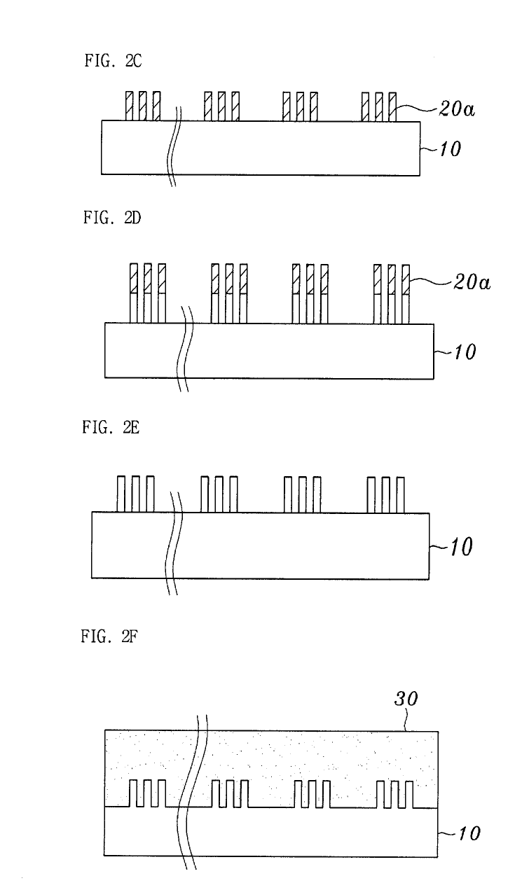

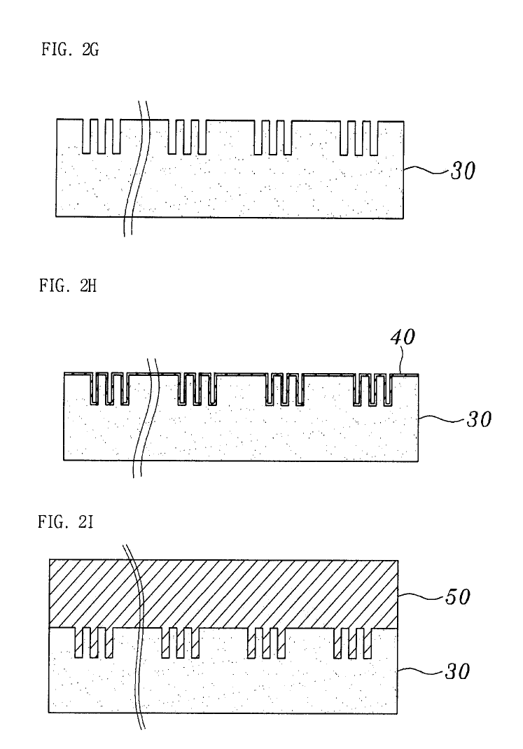

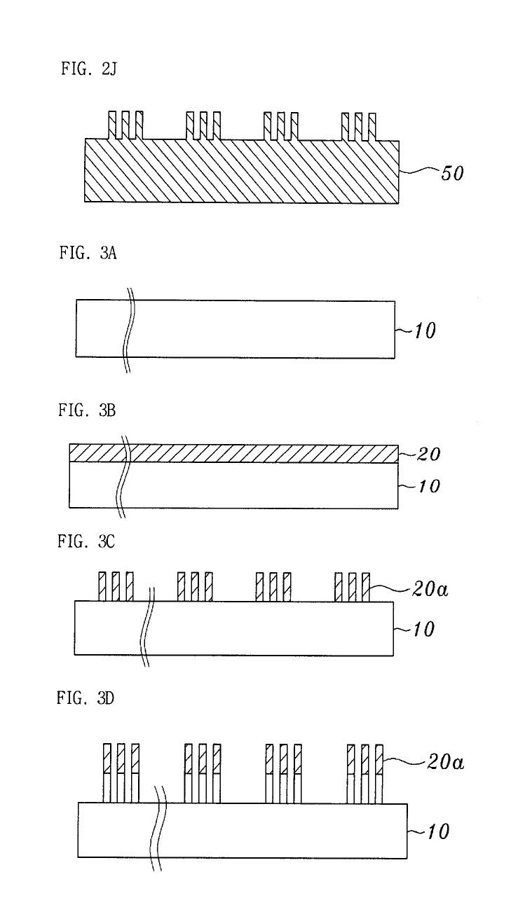

FIGS. 2A to 2J are sectional views illustrating a method of manufacturing a solvent-soluble stamp for nano-imprint lithography according to the first exemplary embodiment of the present invention.

As shown in FIGS. 2A and 2B, first, a resist 20 is coated on the upper surface of a substrate 10 made from an ultraviolet-permeable material such as silicon Si, glass, quartz, sapphire, diamond, etc. In this case, an ultraviolet-curing polymer material is preferably used as the resist 20.

Then, a pattern is formed on the substrate 10 coated with the resist 20 by using a lithography process such as photo-lithography, E-beam lithography, etc.

Next, a pattern is lithographed on the substrate 10 by using a Reaction Ion Etching (RIE) process, in order to make a mask 20a, as shown in FIG. 2C.

Continuously, the substrate 10 is etched using the mask 20a as an etching barrier layer and then the mask 20a is removed, as shown in FIGS. 2D and 2E.

Sequentially, a polymer 30, such as resin, which is soluble in a solvent, is vapor-deposited on the structure of FIG. 2E and then solidified in order to lithograph the pattern of the substrate, as shown in FIG. 2F.

Then, the polymer 30 on which the pattern of the substrate 10 is lithographed is physically separated from the substrate 10, as shown in FIG. 2G. At this time, since the polymer 30 is not chemically bonded to the substrate 10, the separation of the polymer 30 from the substrate 10 can be easily achieved. Thus, damage to the substrate can be prevented.

After that, a metal layer 40 for plating is vapor-deposited on the upper surface of the pattern of the polymer 30 using a sputtering method, as shown in FIG. 2H. When the plating is completed, electric current can flow through an electroplated layer.

Next, a metal such as nickel Ni or copper Cu is vapor-deposited on the upper surface of the structure of FIG. 2H, using the electroplating method, so as to form a metal stamp 50, as shown in FIG. 2I.

Finally, as shown in FIG. 2J, the polymer 30 is solved and removed by the solvent, so that the stamp 50 for nano-imprint lithography can be manufactured.

### Embodiment 2

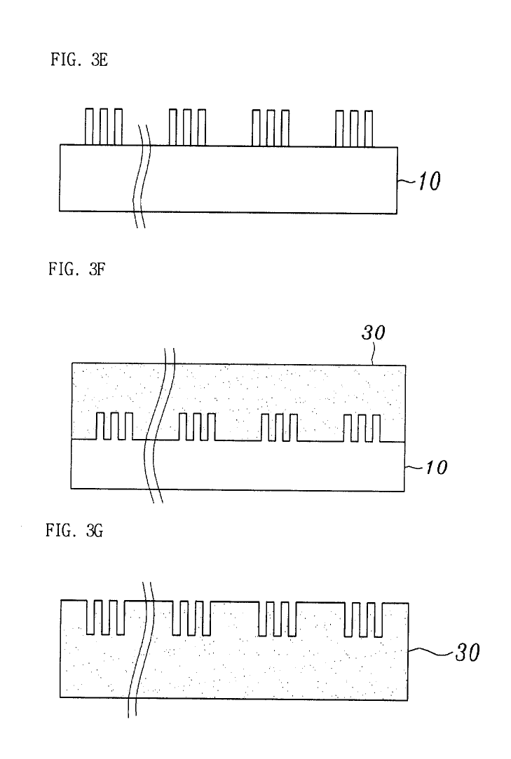

FIGS. 3A to 3E are sectional views illustrating a method of manufacturing a solvent-soluble stamp for nano-imprint lithography according to the second exemplary embodiment of the present invention.

In the method of manufacturing the solvent-soluble stamp for nano-imprint lithography according to the second embodiment of the present invention, a pattern is lithographed on a polymer 30 using the same processes as those of the first exemplary embodiment of FIGS. 2A to 2G. Then, the patterned polymer 30 can be used as the stamp.

As described above, in the method of manufacturing the solvent-soluble stamp for nano-imprint lithography according to the present invention, a pattern is formed on a substrate 10 using a conventional method. Then, a solvent-soluble polymer 30 is filled in the pattern, which in turn is solidified so that the pattern is lithographed. Next, the polymer 30 is separated from the substrate 10. In this case, since the polymer 30 is not chemically bonded to the substrate 10, the separation of the polymer 30 from the substrate 10 can be easily achieved. Thus, damage to the substrate can be prevented. A metal 40 is vapor-deposited on the separated polymer substrate 30 using a sputtering method so as to form an electrode, and then plating is carried out. After the metal stamp 50 is manufactured by the plating, the stamp 50 is immersed in the solvent in order to remove the polymer, so that the clean and accurate stamp with the nano-pattern can be obtained. Further, since the original substrate is not damaged, a number of stamps can be duplicated.

As described above, in the method of manufacturing the stamp for nano-imprint lithography, a stamp is formed on a master substrate made of an ultraviolet-transparent material such as silicon Si, glass, quartz, sapphire, diamond, etc., using a material which is soluble in a solvent, and then a metal stamp or another stamp for nano-imprint lithography is manufactured using the solvent-soluble stamp. Next, the stamp for nano-imprint lithography can be achieved by melting the soluble stamp. Therefore, it is possible to reuse the master several times. Further, it is possible to solve a problem in which a mold cannot be separated from the stamp. Furthermore, a uniform and clean stamp with a nano size can be obtained.

Further, the stamp can be manufactured using the solvent-soluble polymer after the pattern is formed on the substrate by the conventional method.

Furthermore, a number of stamps can be duplicated using only one substrate.

While an exemplary embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method of manufacturing a solvent-soluble stamp for nano-imprint lithography, the method comprising:
(a) forming a pattern on the upper surface of a substrate using a lithography process after a resist is coated on the upper surface of the substrate;
(b) etching the substrate using the patterned resist;
(c) vapor-depositing a polymer on the structure in step (b);
(d) physically separating the polymer on which the pattern of the substrate is lithographed from the substrate;
(e) vapor-depositing a metal layer for plating on the upper surface of the separated polymer pattern using a sputtering process;
(f) vapor-depositing a metal on the upper surface of the structure in step (e) by electroplating method; and
(g) solving the structure in step (f) in the solvent to remove the polymer, so as to obtain the stamp for nano-imprint lithography.

2. A method of manufacturing a solvent-soluble stamp for nano-imprint lithography, the method comprising:
(a) forming a pattern on the upper surface of a substrate using a lithography process after a resist is coated on the upper surface of the substrate;
(b) etching the substrate using the patterned resist;
(c) vapor-depositing a polymer such as solvent-soluble resin on the structure in step (b); and
(d) physically separating the polymer on which the pattern of the substrate is lithographed from the substrate, so as to obtain the stamp for nano-imprint lithography.

3. The method as claimed in claim 1, wherein the substrate is made from an ultraviolet-permeable material selected from silicon Si, glass, quartz, sapphire, and diamond.

4. The method as claimed in claim 2, wherein the substrate is made from an ultraviolet-permeable material selected from silicon Si, glass, quartz, sapphire, and diamond.

5. The method as claimed in claim 1, wherein the metal deposited on the structure in step (f) includes nickel Ni and copper Cu.

6. The method as claimed in claim 1, wherein etching the substrate using the patterned resist includes using the patterned resist as an etching barrier.

7. The method as claimed in claim 1, wherein the polymer is a solvent soluble resin.

8. The method as claimed in claim 2, wherein etching the substrate using the patterned resist includes using the patterned resist as an etching barrier.

9. The method as claimed in claim 2, wherein the polymer is a solvent soluble resin.
